(19) United States
(12) Patent Application Publication
(10) Pub. No.: US 2022/0330436 A1
(43) Pub. Date: Oct. 13, 2022

(54) SUBSTRATE PROCESSING APPARATUS AND SUBSTRATE PROCESSING METHOD FOR MANUFACTURING FLEXIBLE CIRCUIT BOARD

(71) Applicant: PROTEC CO., LTD., Gyeonggi-do (KR)

(72) Inventors: Seung Min HONG, Seoul (KR); EUI KEUN CHOI, Seoul (KR)

(73) Assignee: PROTEC CO., LTD., Gyeonggi-do (KR)

(21) Appl. No.: 17/852,332

(22) Filed: Jun. 28, 2022

Related U.S. Application Data
(63) Continuation of application No. PCT/KR2020/015396, filed on Nov. 5, 2020.

(30) Foreign Application Priority Data
Dec. 30, 2019 (KR) 10-2019-0177555

(51) Int. Cl. H05K 3/12

(52) U.S. Cl. CPC H05K 3/125; H05K 2203/013; H05K 2203/095

(57) ABSTRACT

The present disclosure relates to a substrate processing apparatus and a substrate processing method, for manufacturing a flexible circuit board, and more specifically, to a substrate processing apparatus and a substrate processing method, for manufacturing a flexible circuit board, capable of manufacturing a flexible circuit board with a fine line width without undergoing a photolithographic process using a mask.

The substrate processing apparatus and the substrate processing method, for manufacturing a flexible circuit board, according to the present disclosure, can efficiently manufacture a flexible circuit board having a fine line width at low costs.

This application is a continuation of PCT International Application No. PCT/KR2020/015396, filed on Nov. 5, 2020, which claims priority under 35 U.S.C § 119(a) to Korean Patent Application No. 10-2019-0177555, filed on Dec. 30, 2019. Each of the above application(s) is hereby expressly incorporated by reference, in its entirety, into the present application.

### TECHNICAL FIELD

The present disclosure relates to a substrate processing apparatus and a substrate processing method for manufacturing flexible circuit boards, and more particularly relates to a substrate processing apparatus and a substrate processing method capable of manufacturing flexible circuit boards having a fine line width without going through a photolithographic process using a mask.

### BACKGROUND ART

Flexible circuit boards are widely used in a process of miniaturization and high performance of semiconductor parts and electronic products.

A photolithographic process using a mask is widely used in the process of manufacturing such the flexible circuit boards.

The mask that may realize a circuit with a fine line width is manufactured, and a process of exposing light to material coated with photosensitive material is performed by using the mask, and then various processes such as development, etching are performed to manufacture the flexible circuit boards.

However, this method of using the mask may produce a sophisticated flexible circuit boards having the fine line width, but it takes a lot of time and money to produce the mask. In addition, the flexible circuit manufacturing method using the mask undergoes complex processes such as the development process and an etching process in addition to the process of exposing light.

In particular, in the case of products produced in small quantities with multiple types, it is cumbersome and inefficient as the mask has to be made every time according to the circuit pattern.

Therefore, there is a need for an apparatus and method capable of efficiently manufacturing flexible circuit boards having a fine line width without going through the photolithographic process using the mask.

### DESCRIPTION OF EMBODIMENTS

### Technical Problem

An object of the present disclosure is to provide a substrate processing apparatus and a substrate processing method capable of efficiently manufacturing flexible circuit boards having a fine line width without using a mask.

### Technical Solution to Problem

A substrate processing apparatus for manufacturing flexible circuit boards of this disclosure for achieving the above object includes a dispensing module including a dispensing base on which a thin copper layer material is disposed, an inkjet head disposed on an upper side of the dispensing base and ejecting a viscous solution having an etching resist characteristic in an inkjet manner to a position where a circuit is to be formed on the thin copper layer material disposed on the dispensing base, and a dispensing transfer unit for transferring the inkjet head; and a control module for controlling an operation of the dispensing module.

In addition, a substrate processing method for manufacturing flexible circuit boards of the present disclosure includes (a) placing a thin copper layer material on a dispensing base; and

(b) dispensing a viscous solution having an etching resist characteristic in an inkjet manner while transferring an inkjet head along a path on which a circuit is to be formed on the thin copper layer material disposed on the dispensing base.

### Advantageous Effects of Disclosure

A substrate processing apparatus and a substrate processing method for manufacturing flexible circuit boards according to the present disclosure may efficiently manufacture flexible circuit boards having a fine line width at low cost.

### BRIEF DESCRIPTION OF DRAWINGS

FIG. 1 is a plan view of a substrate processing apparatus for manufacturing flexible circuit boards according to an embodiment of the present disclosure.

FIG. 2 is a front view of the substrate processing apparatus for manufacturing flexible circuit boards illustrated in FIG. 1.

FIGS. 3 to 5 are schematic diagrams for explaining a process of implementing an example of a substrate processing method for manufacturing flexible circuit boards according to the present disclosure using the substrate processing apparatus for manufacturing flexible circuit boards illustrated in FIGS. 1 and 2.

### MODE OF DISCLOSURE

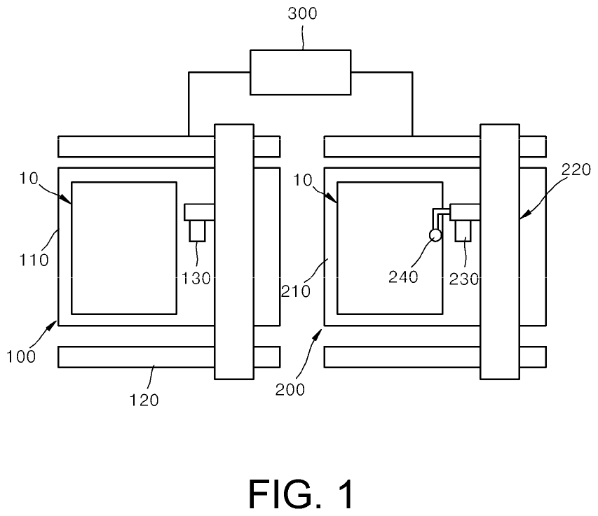

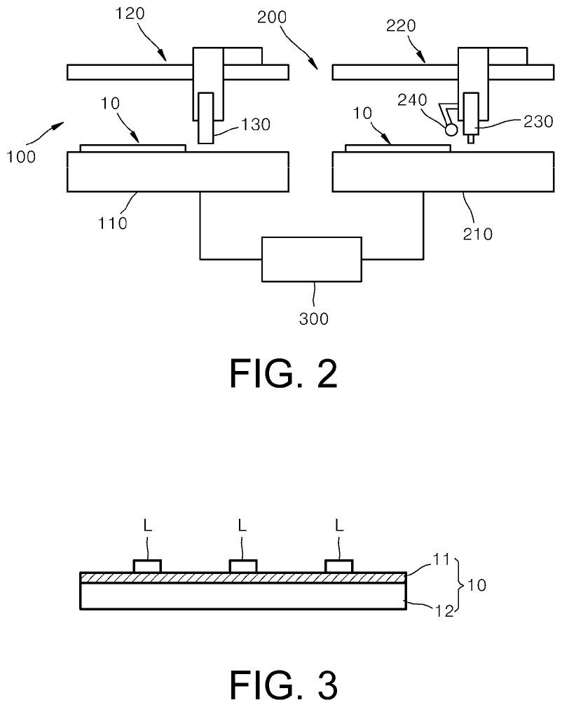

Hereinafter, a substrate processing apparatus for manufacturing flexible circuit boards according to an embodiment of the present disclosure will be described with reference to FIGS. 1 and 2.

FIG. 1 is a plan view of a substrate processing apparatus for manufacturing flexible circuit boards according to an embodiment of the present disclosure, and FIG. 2 is a front view of the substrate processing apparatus for manufacturing flexible circuit boards illustrated in FIG. 1.

Referring to FIGS. 1 and 2, a substrate processing apparatus for manufacturing flexible circuit boards of this embodiment includes a plasma module 100, a dispensing module 200 and a control module 300.

The plasma module 100 includes a plasma base 110, a plasma head 130 and a plasma transfer unit 120.

In the plasma base 110, a thin copper layer material 10, which is a target material for performing a process according to the present disclosure, is disposed.

The thin copper layer material is formed in a state in which the thin copper layer 11 is attached to an insulating film 12. The thin copper layer material 10 thus formed is disposed and fixed on the plasma base 110.

The plasma head 130 generates plasma. In this embodiment, the plasma head 130 locally generates plasma by a high voltage under atmospheric pressure.

The plasma transfer unit 120 exposes the plasma to a required position of the thin copper layer material 10 on the plasma base 110 while elevating and moving the plasma head 130 forward and backward with respect to the plasma base 110.

The control module 300 controls operations of the plasma transfer unit 120 and the plasma head 130.

The control module 300 receives a pattern information for a part remaining after a portion of the thin copper layer 11 of the thin copper layer material 10 is removed to form a circuit, and operates the plasma transfer unit 120 and the plasma head 130 according to the pattern information. That is, the control module 300 operates the plasma head 130 and the plasma transfer unit 120 so that a region where the circuit is to be formed among the thin copper layer material 10 is exposed to plasma.

By performing the plasma treatment on the upper surface of the thin copper layer material 10 as described above, the plasma module 100 changes a surface property of the corresponding area of the thin copper layer material 10 from conventional phobic property to philic property. As such, by changing the surface property of the thin copper layer material 10 through the plasma treatment, a viscous solution L, which will be described later, spreads well in the thin copper layer material 10.

The dispensing module 200 includes a dispensing base 210, an inkjet head 230, a dispensing transfer unit 220 and an ultraviolet lamp 240.

The thin copper layer material 10 that has been plasma treated by the plasma module 100 is placed and fixed on the dispensing base 210. The thin copper layer material 10 may be transferred from the plasma module 100 to the dispensing module 200 by an automatic transfer device. In some cases, the thin copper layer material 10 may be transferred from the plasma module 100 to the dispensing module 200 by an operator.

The inkjet head 230 is disposed on an upper side of the dispensing base 210. The inkjet head 230 dispenses a viscous solution L onto the thin copper layer material 10 in an inkjet manner. The viscous solution L dispensed from the inkjet head 230 has an etching resist character and photocurability. That is, the viscous solution L is dispensed to the thin copper layer 11 to prevent etching of the thin copper layer 11 in the corresponding area. Also, since the viscous solution L has photocurability, the viscous solution L is hardened when exposed to ultraviolet light.

The dispensing transfer unit 220 transfers the inkjet head 230 to the front, back, left and right with respect to the dispensing base 210 and elevates the inkjet head. That is, the dispensing transfer unit 220 transfers the inkjet head 230 to dispense the viscous solution L along the pattern for forming the circuit on the thin copper layer material 10.

The ultraviolet lamp 240 is installed in the dispensing transfer unit 220, and is moved together with the inkjet head 230. The ultraviolet lamp 240 is arranged to irradiate ultraviolet light to a point where the viscous solution L ejected from the inkjet head 230 reaches the thin copper layer material 10.

As described above, the control module 300 controls the operations of the plasma module 100 and the dispensing module 200. The control module 300 transmits a droplet ejection signal to the inkjet head 230 while allowing the dispensing transfer unit 220 to move the inkjet head 230 along a pre-input path. At the same time, the control module 300 transmits a signal to blink the ultraviolet lamp 240 to the ultraviolet lamp 240. Considering time it takes for a droplet of the viscous solution L to be ejected after the inkjet head 230 is operated, the control module 300 turns on the ultraviolet lamp 240 when the time elapses after transmitting the ejection signal to the inkjet head 230 and then turns off the ultraviolet lamp.

Hereinafter, a process of performing a substrate processing method for manufacturing flexible circuit boards using the substrate processing apparatus for manufacturing flexible circuit boards configured as described above will be described.

First, the plasma treatment is performed on the thin copper layer material 10 by using the plasma module 100 (step (d)).

As described above, the thin copper layer material 10 is disposed and fixed on the plasma base 110 of the plasma module 100.

At this time, the pattern of the circuit to be formed on the thin copper layer material 10 is stored in the control module 300.

The control module 300 performs the plasma treatment by operating the plasma transfer unit 120 and the plasma head 130 according to the pattern of the circuit to be formed on the thin copper layer material 10. As described above, the plasma head 130 locally generates plasma by using the high voltage under atmospheric pressure without using a gas such as argon or using a vacuum state.

The control module 300 drives the plasma transfer unit 120 so that a nozzle of the plasma head 130 moves close to an upper surface of the thin copper layer material 10 according to a predetermined pattern. By performing the plasma treatment in this way, as described above, the required area of the thin copper layer material 10 is treated so as to be in the philic state. As described above, the path through which the plasma head 130 passes corresponds to the path to which the viscous solution L will be applied later by the dispensing module 200. In order to perform plasma treatment along the predetermined path in this way, the plasma module 100 may include a camera. After the control module 300 detects a position and direction of the thin copper layer material 10 by using the camera, and operates the plasma transfer unit 120 according to the position and direction.

Next, the thin copper layer material 10 on which the plasma treatment has been completed is placed and fixed on the dispensing base 210 of the dispensing module 200 (step (a)).

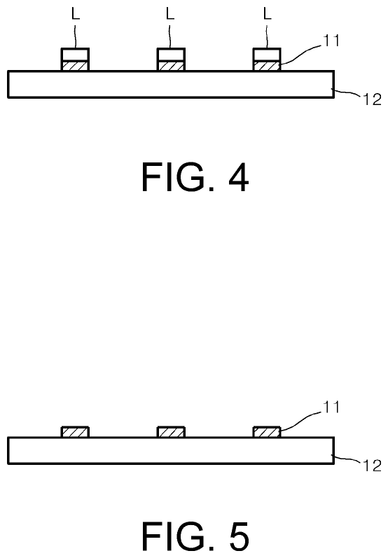

In this state, as illustrated in FIG. 3, the control module 300 operates the dispensing transfer unit 220 and the inkjet head 230 to ejection the viscous solution L along the path where the circuit is to be formed on the thin copper layer material 10 (step (b)).

At this time, the control module 300 operates an ultraviolet lamp 240 to irradiate ultraviolet light to the viscous solution L dispensed on the thin copper layer material 10 (step (c)).

As described above, the viscous solution L is formed of a liquid resin mixture having the photocurability and the etching resist characteristic. Accordingly, the viscous solution L dispensed on the thin copper layer material 10 is immediately hardened when exposed to ultraviolet light.

Since the dispensing module 200 uses the inkjet head 230 that ejects the viscous solution L in the inkjet manner, the dispensing module is possible to dispense the viscous solution L with a line width of about 50 μm or thinner. In addition, as described above, since the viscous solution L having the photocurability is used and ultraviolet light is irradiated with the ultraviolet lamp 240, it is prevented that the viscous solution L flows to unnecessarily thicken the line width or the viscous solution is applied to an unnecessary area. In particular, as in this embodiment, when dispensing and curing are simultaneously performed while the inkjet head 230 and the ultraviolet lamp 240 are moved together with the inkjet head 230 by the dispensing transfer unit 220, a circuit having a very thin line width may be easily formed.

On the other hand, as described above, since the area to be coated with the viscous solution L on the thin copper layer material 10 was plasma-treated and treated in a philic state in advance by the plasma module 100, the line width is prevented from becoming non-uniform due to a surface tension of the viscous solution L. That is, when the surface of the thin copper layer material 10 is phobic, defect in which the viscous solution L is not applied to the required area may occur due to the surface tension of the applied viscous solution L. However, due to the plasma treatment as described above, the present disclosure makes it possible to maintain a uniform and precise dispensing quality of the viscous solution L. Accordingly, the present disclosure makes it possible to easily fabricate flexible circuit boards of various shapes without having to newly manufacture the mask required for a conventional photolithography process every time.

Meanwhile, in step (c) described above, the control module 300 transmits the droplet ejection signal to the inkjet head 230 and then turns on the ultraviolet lamp 240 after the predetermined time has elapsed, so that the dispensing quality may be further improved. Considering time for the droplet to reach the thin copper layer material 10 after the control module 300 transmits the droplet ejection signal to the inkjet head 230, the control module turns on the ultraviolet lamp 240 and then turns off the ultraviolet lamp after the time elapses, so that the quality of dispensing process may be further improved. That is, the nozzle of the inkjet head 230 is prevented from clogging by not exposing the viscous solution L of the inkjet head 230 to ultraviolet light unnecessarily and exposing it to ultraviolet light only when the viscous solution L requiring curing reaches the thin copper layer material 10. In addition, by this method, sufficient viscosity may be maintained until the viscous solution L reaches the thin copper layer material 10.

The dispensing module 200 may further include the camera. The control module 300 may use the camera of the dispensing module 200 to photograph the position and direction of the thin copper layer material 10 disposed on the dispensing base 210, and drive the dispensing transfer unit 220 according to the position and direction of the thin copper layer material 10.

When the dispensing process of dispensing the viscous solution L to the thin copper layer material 10 is completed as described above, the viscous solution L is applied to the required area of the thin copper layer material 10 and hardened, as illustrated in FIG. 3.

In this way, in a state where both steps (b) and (c) are completed, a process of further curing the viscous solution L on the thin copper layer material 10 by irradiating the thin copper layer material 10 with ultraviolet light may also be additionally performed if necessary (step (e)).

When the etching process is performed on the thin copper layer material 10 on which dispensing and curing of the viscous solution L has been completed, only the thin copper layer 11 in the area where the viscous solution L is not dispensed is removed, and only circuit with very fine line width remains in the thin copper layer material 10 as illustrated in FIG. 4.

In this state, as illustrated in FIG. 5, if a peeling process for removing the hardened viscous solution L is performed, a process of configuring one layer of the flexible circuit board is completed.

If a process of attaching a coverlay film or applying a resin solution corresponding to the coverlay layer and other subsequent processes are performed in this state, the flexible circuit boards may be manufactured.

In the case of manufacturing the flexible circuit boards in this way, there is no need to perform the process of manufacturing the mask and a process of photosensitizing and developing a photoresist layer, so that the flexible circuit boards with the fine line width may be manufactured while reducing the cost. In addition, since the mask is not used, flexible circuit boards that are produced in small quantities of various types may be efficiently produced. In addition, unlike the case of manufacturing the flexible circuit boards by the conventional photolithographic process, since there is no need to form an adhesive layer, flexible circuit boards having a thinner thickness than the conventional one may be manufactured with high quality.

In the above, a preferred example has been described for the present disclosure, but the scope of the present disclosure is not limited to the form described and illustrated above.

For example, the substrate processing apparatus for manufacturing flexible circuit boards of the present disclosure has been described as having the plasma module 100, but in some cases, a substrate processing apparatus for manufacturing flexible circuit boards that does not have the plasma module 100 may be configured, or a substrate processing method for manufacturing flexible circuit boards that omits the plasma treatment process may be practiced. Depending on the characteristics of the viscous solution L and the surface characteristics of the thin copper layer material 10, the plasma treatment process may be omitted.

In addition, although it has been described previously that the viscous solution L having photocurability and the ultraviolet lamp 240 are used, but in some cases, it is also possible to use a viscous solution cured by temperature without using the viscous solution L having photocurability. In this case, the process of irradiating ultraviolet light to the viscous solution may be omitted.

In addition, it has been explained that it is possible to perform the additional curing process of irradiating the entire thin copper layer material 10 with ultraviolet light if necessary after all the steps of dispensing the viscous solution L are completed, but it is also possible to implement a substrate processing method for manufacturing flexible circuit boards.

In addition, in consideration of the difference between the time when the droplet ejection signal is generated by the control module 300 and the time when the droplet of the viscous solution L is ejected from the inkjet head 230 and reached the surface of the thin copper layer material 10, it has been described that the ultraviolet lamp 240 is turned on after the predetermined time has elapsed and then turned off, but in some cases, it is also possible to perform a step of dispensing the viscous solution L in a state in which the ultraviolet lamp 240 is continuously turned on.

1. A substrate processing apparatus for manufacturing flexible circuit boards, the substrate processing apparatus comprising:
a dispensing module comprising
a dispensing base on which a thin copper layer material is disposed,
an inkjet head disposed on an upper side of the dispensing base and ejecting a viscous solution having an etching resist characteristic in an inkjet manner to a position where a circuit is to be formed on the thin copper layer material disposed on the dispensing base, and
a dispensing transfer unit for transferring the inkjet head; and
a control module for controlling an operation of the dispensing module.

2. The substrate processing apparatus of claim 1, wherein
the dispensing module further comprises an ultraviolet lamp for irradiating ultraviolet light to the viscous solution ejected by the inkjet head, and
the viscous solution dispensed from the inkjet head of the dispensing module is a material having the etching resist characteristic and a photocurability.

3. The substrate processing apparatus of claim 2, wherein the ultraviolet lamp of the dispensing module is installed in the dispensing transfer unit to be transferred together with the inkjet head.

4. The substrate processing apparatus of claim 3, wherein the control module transmits a signal for turning on the ultraviolet lamp to the ultraviolet lamp after a predetermined time has elapsed after transmitting a droplet ejection signal to the inkjet head.

5. The substrate processing apparatus of claim 1, further comprising
a plasma module for performing plasma treatment on a position where the viscous solution is to be applied on the thin copper layer material,
wherein the control module controls an operation of the plasma module, and
the dispensing module applies the viscous solution on the thin copper layer material on which the plasma treatment is completed by the plasma module.

6. The substrate processing apparatus of claim 5, wherein the plasma module comprises
a plasma base on which the thin copper layer material is disposed,
a plasma head for locally generating plasma under atmospheric pressure on the thin copper layer material, and
a plasma transfer unit for transferring the plasma head with respect to the plasma base so as to expose the plasma generated in the plasma head along a path through which the viscous solution is to be applied to the thin copper layer material.

7. A substrate processing method for manufacturing flexible circuit boards, the substrate processing method comprising:
(a) placing a thin copper layer material on a dispensing base; and
(b) dispensing a viscous solution having an etching resist characteristic in an inkjet manner while transferring an inkjet head along a path on which a circuit is to be formed in the thin copper layer material disposed on the dispensing base.

8. The substrate processing method of claim 7, further comprising
(c) irradiating ultraviolet light to the viscous solution ejected onto the thin copper layer material by using an ultraviolet lamp;
wherein, in (b), the viscous solution which is a material having the etching resist characteristic and a photocurability is ejected by the inkjet head.

9. The substrate processing method of claim 8, wherein, in (c), the ultraviolet lamp irradiates ultraviolet light to the viscous solution ejected from the inkjet head while moving together with the inkjet head.

10. The substrate processing method of claim 9, wherein, in (c), the ultraviolet lamp is turned on after a predetermined time has elapsed after a droplet ejection signal is transmitted to the inkjet head.

11. The substrate processing method of claim 7, further comprising
(d), before (a), performing plasma treatment on a position where the viscous solution is to be applied on the thin copper layer material.

12. The substrate processing method of claim 11, wherein (d) comprises
placing the thin copper layer material on a plasma base, and
exposing plasma generated from a plasma head along a path through which the viscous solution is to be applied on the thin copper layer material while transporting the plasma head locally generating plasma under atmospheric pressure on the thin copper layer material disposed on the plasma base.

13. The substrate processing method of claim 11, further comprising
(e) irradiating the thin copper layer material with ultraviolet light as a whole after completion of (b) and (c).
